(19) United States
(12) Patent Application Publication
(10) Pub. No.: US 2006/0097621 A1
(43) Pub. Date: May 11, 2006

(54) White light emitting diode package and method of manufacturing the same

(75) Inventors: Il Woo Park, Suwon (KR); Yun Seup Chung, Seoul (KR); Chul Soo Yoon, Suwon (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: Samsung Electro-Mechanics Co., Ltd., Suwon (KR)

(21) Appl. No.: 11/145,817

(22) Filed: Jun. 6, 2005

(30) Foreign Application Priority Data
Nov. 5, 2004 (KR) 10-2004-89870

(51) Int. Cl. H05B 33/04; H01L 51/50

(52) U.S. Cl. 313/485; 313/486; 313/512

(57) ABSTRACT

A method of manufacturing a white light emitting diode package comprises the steps of mounting a light emitting diode on a package substrate having at least one lead frame, preparing phosphor paste having a viscosity of 500˜10,000 cps by mixing phosphor powders and a transparent polymer resin, dispensing liquid droplets of the phosphor paste on an upper surface of the light emitting diode such that the phosphor paste is applied onto the upper surface and side surfaces of the light emitting diode, and curing the phosphor paste applied onto the light emitting diode.

### RELATED APPLICATION

The present invention is based on, and claims priority from, Korean Application Number 2004-89870, filed on Nov. 5, 2004, the disclosure of which is incorporated by reference herein in its entirety.

### BACKGROUND OF THE INVENTION

1. Field of the Invention

The present invention relates to a white light emitting diode, and more particularly to a method of manufacturing a white light emitting diode package, which has a phosphor for wavelength conversion applied onto a light emitting diode emitting short wavelength light.

2. Description of the Related Art

Generally, light emitting diodes (LEDs) have advantages in view of excellent monochromatic light in a peak wavelength, excellent optical efficiency, and of miniaturization, and are used in light source and display apparatus fields. In particular, white light emitting diodes have been actively developed as high power and high efficiency light sources for replacing conventional lighting apparatuses or backlights of displays.

As for a method of realizing such a white light emitting diode, a wavelength conversion method has been generally used, in which near ultraviolet or blue light (370˜480 nm) is converted into white light by means of a phosphor applied onto the LED, which emits the near ultraviolet or blue light.

FIG. 1a is a cross sectional view illustrating a conventional white LED package 10 manufactured by a conventional method.

Referring to FIG. 1a, the white LED package 10 comprises a package substrate 11 having two lead frames 13a and 13b formed thereon, and a blue LED chip 15 mounted within a cap structure 12 of the package substrate 11. The LED chip 15 has a flip-chip structure comprising a light emitting diode 15a and a chip substrate 15b. Electrode terminals (not shown) formed on the chip substrate 15b while being connected to both electrodes (not shown) on the LED chip 15 are connected to upper portions of the lead frames 13a and 13b via wires 14a and 14b, respectively.

The cap structure 12 has a molding portion 19 containing Y—Al—Ga (YAG)-based phosphor powders 18 therein such that the molding portion 19 encloses the blue LED chip 15. The phosphor powders 18 in the molding portion 19 convert some of the blue light emitted from the LED 15a into yellow light, so that the converted yellow light combines with the non-converted blue light and is emitted as white light.

In general, the molding portion 19 acting to convert the wavelength of light can be formed of liquid resins containing the phosphor powders uniformly distributed in the liquid resins by a dispensing process.

However, as shown in FIG. 1b, since the conventional dispensing process uses the liquid resins, there is a problem in that the phosphor powders are deposited during curing of the liquid resins. In worst cases, a very small amount of phosphor powder is distributed in side regions of the light emitting diode chip, as indicated by the arrow A in FIG. 1a, whereby the blue light, emitted without wavelength conversion, can be increased in ratio. Accordingly, a greater amount of phosphor powders is required for the light emitting diode chip, resulting in decrease of brightness of the light emitting diode, and differentiation of the temperature of colors according to a deflection angle, which causes an off-white phenomenon partially emitting yellow-white light or blue-white light.

Moreover, if a reflective surface is provided on an inner surface of the cap structure or the substrate in order enhance the brightness, the deposited phosphor powders are attached to the reflective surface, and decrease the reflection factor of the reflective surface, thereby causing reduction in brightness of the light emitting diode.

If various phosphor powders are mixed, the deposition of the phosphor powders become even more complex. For example, in the case where a white light emitting diode is manufactured by use of an ultraviolet light emitting diode and a mixture of red, green and blue phosphor powders in an appropriate composition, since respective phosphor powders have different specific gravities and powder sizes, non-uniformity of colors become more serious.

Moreover, since the degree of deposition is increased as the dispensing process and curing of the liquid resins proceed, the chromaticity or color coordinates of the diode package are varied according to process time, thereby causing problems of increasing not only the frequency of defective products, but also a degree of dispersion in the color coordinates of the package according to the package.

### SUMMARY OF THE INVENTION

The present invention has been made to solve the above problems, and it is an object of the present invention to provide a method of manufacturing a white light emitting diode package, comprising the step of dispensing high viscosity phosphor paste such that the phosphor paste is uniformly applied onto an upper surface and a side surface of a light emitting diode, thereby enhancing white light characteristics of the light emitting diode package.

In accordance with one aspect of the present invention, the above and other objects can be accomplished by the provision of a method of manufacturing a white light emitting diode package, comprising the steps of: mounting a light emitting diode on a package substrate having at least one lead frame; preparing phosphor paste having a viscosity of 500˜10,000 cps by mixing phosphor powders and a transparent polymer resin; dispensing liquid droplets of the phosphor paste on an upper surface of the light emitting diode such that the phosphor paste is applied onto the upper surface and side surfaces of the light emitting diode; and curing the phosphor paste applied onto the light emitting diode.

The phosphor paste may have a weight ratio of the paste powders to the transparent polymer resin in the range of 0.5˜10. The liquid droplet of the phosphor paste may have a volume of 0.012˜0.5 μl.

The transparent polymer resin may be a curable polymer resin, and the curable polymer resin may be a silicon-based polymer resin or an epoxy-based polymer resin.

In order to prevent undesired flow of the phosphor paste due to wires, the method may further comprise the step of electrically connecting the light emitting diode or the light emitting diode chip to the lead frame by use of the wires after the step of curing the phosphor paste. With regard to this, if the undesired flow of the phosphor paste can be suppressed by controlling a height of wires, the wire boding process may be performed upon mounting the light emitting diode. Furthermore, the present invention may be applied to various package structures, such as a flip chip light emitting diode.

The package substrate may comprise a cap structure enclosing the light emitting diode on an upper surface of the package substrate. In this case, the method of the present invention further comprise the step of forming a transparent molding portion inside the cap structure by use of the transparent resin after the step of curing the phosphor paste.

In accordance with another aspect of the present invention, there is provided a white light emitting diode package manufactured by the method as described above.

According to the present invention, the phosphor paste having the viscosity of 500˜10,000 cps is prepared, and supplied to the upper surface of the light emitting diode in a small amount, such that the phosphor paste can be applied only onto the upper surface and the side surfaces of the light emitting diode. Accordingly, the method of the invention can solve the problems of the conventional method using deposition of phosphor powders, allow the phosphor paste to be uniformly applied to the side surfaces as well as the upper surface of the light emitting diode, thereby providing excellent light transformation efficiency, and can prevent a decrease in brightness caused by attachment of the phosphor powders to reflective regions, including the upper surface of the package substrate.

### BRIEF DESCRIPTION OF THE DRAWINGS

The foregoing and other objects and features of the present invention will be more clearly understood from the following detailed description taken in conjunction with the accompanying drawings, in which:

FIG. 1a is a schematic cross-sectional view illustrating a conventional white light emitting diode package;

FIG. 1b is a picture of a convention white light emitting diode package having a similar structure to that of the white light emitting diode package of FIG. 1a, which was taken using a scanning electron microscope (SEM);

FIGS. 2a to 2d are flow diagrams illustrating a method of manufacturing a white light emitting diode package in accordance with one embodiment of the present invention;

FIG. 3a is a picture of a white light emitting diode package in accordance with one embodiment of the present invention, which was taken using the SEM, and FIG. 3b is a picture of an upper surface of the white light emitting diode package in accordance with one embodiment of the present invention; and

FIG. 4 is a picture of a white light emitting diode package of a comparative example taken by use of the SEM, and illustrating an applied state of a phosphor film on the white light emitting diode package of the comparative example.

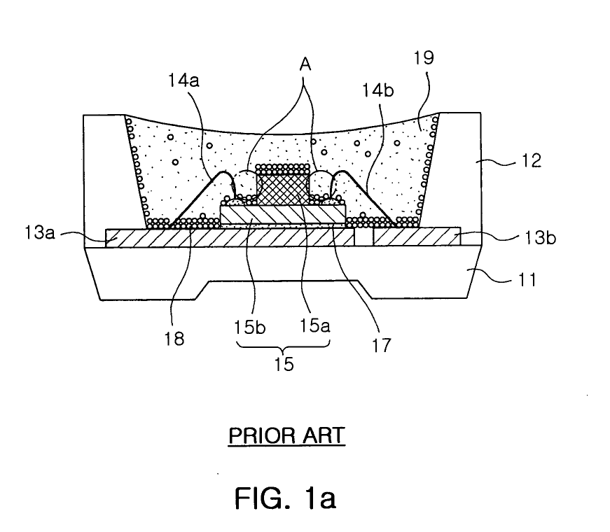

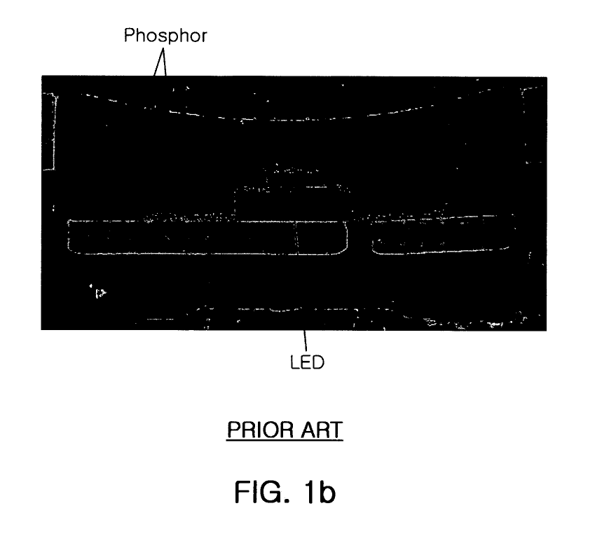

### DESCRIPTION OF THE PREFERRED EMBODIMENTS

Preferred embodiments will now be described in detail with reference to the accompanying drawings.

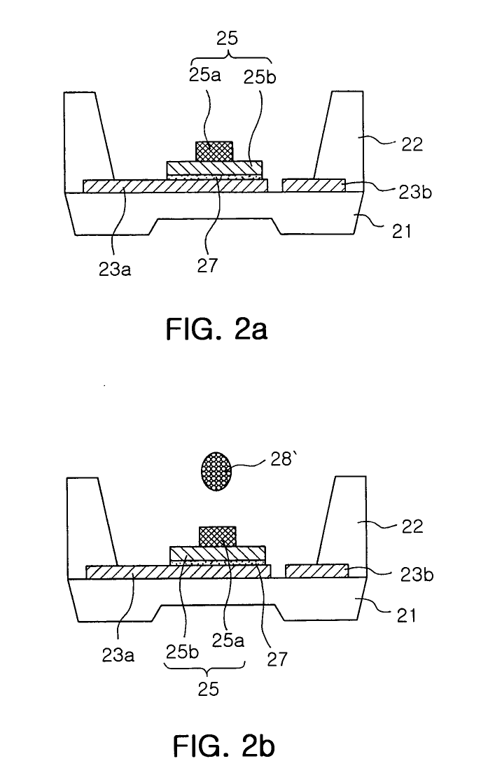

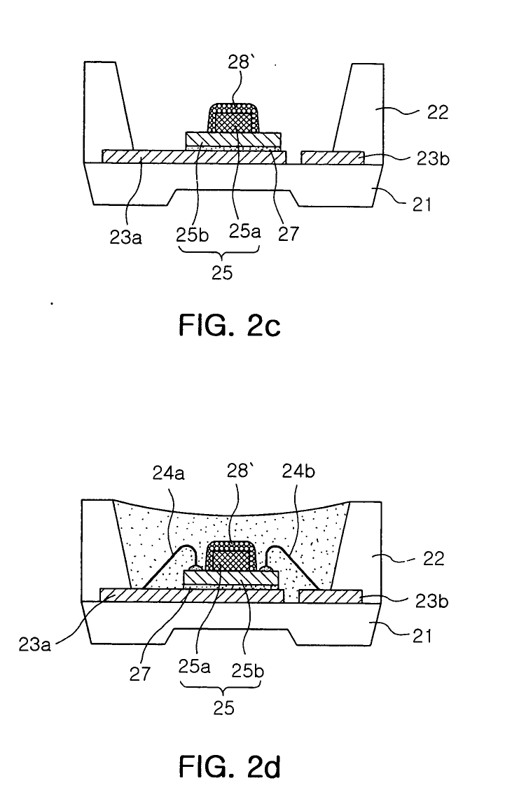

FIGS. 2a to 2d are flow diagrams of a method of manufacturing a white light emitting diode package in accordance with one embodiment of the present invention.

As shown in FIG. 2a, a light emitting diode 25a is mounted on a package substrate 21 having lead frames 23a and 23b. The lead frames 23a and 23b are electrically connected to the light emitting diode 25a. The package substrate 21 may further include a cap structure 22, which has an inclined reflection surface therein, as long as an implementation of the cap structure 22 can be satisfied. The light emitting diode 25a may be a light emitting diode, which emits short wavelength light, such as ultraviolet, near ultraviolet, blue light and the like, and may generally be provided as a light emitting diode chip 25. In the present embodiment, the light emitting diode 25a is mounted on a chip substrate 25b by a flip-chip bonding method, and is thus exemplified as a flip-chip light emitting diode 25. The light emitting diode chip 25 may be mounted on the package substrate 21 with a bonding means, such as adhesives 27.

Next, as shown in FIG. 2b, liquid droplets of phosphor paste 28′ are dispensed on an upper surface of the light emitting diode 25a by a dispensing process. The phosphor paste 28′ of the present invention is a high viscosity phosphor paste having a viscosity of 500˜10,000 cps. The high viscosity phosphor paste 28′ may be prepared by mixing phosphor powders and a transparent polymer resin to have a weight ratio of the paste powders to the transparent polymer resin in the range of 0.5˜10. The phosphor paste having such a weight ratio can have a higher viscosity than a phosphor mixture (transparent polymer resin:phosphor powder=10:1) used in a conventional dispensing process.

The transparent polymer resin of the present invention preferably includes curable resins and acryl-based resin. However, water-soluble resins do not provide sufficient viscosity and are not appropriate for the present invention. As for the curable resins preferably used for the present invention, there are silicon-based polymer resins and epoxy-based polymer resins.

As a result, as shown in FIG. 2c, the phosphor paste 28′ is applied only onto the upper and side surfaces of the light emitting diode 25a by the dispensing process, and is then cured thereon under predetermined conditions (using heat or ultraviolet light). As shown in FIG. 2c, in order to allow the phosphor paste to be applied onto the upper surface and the side surfaces of the light emitting diode 25a, it is necessary to control the volume of the phosphor droplet dispensed on one light emitting diode together with the viscosity of the phosphor paste. The phosphor droplet can have different volumes depending on the size and shape of the light emitting diode 25a. When considering the size and shape of the light emitting diode 25a, the phosphor droplet preferably has a volume of 0.012˜0.5 As such, a cured phosphor film can be adjusted in thickness by means of the volume of the droplet, and additionally, the thickness of the phosphor film on the upper and side surfaces of the light emitting diode can be adjusted by appropriately controlling the viscosity and curing time before the completely cured phosphor film is obtained. For example, in the case of side-view light emitting diode (side-view LED), since a relatively thick phosphor film is required for the side surface of the LED, it can be obtained by setting the viscosity of the phosphor to be relatively low or by extending the curing time before the completely cured phosphor film is obtained after dispensing. Although the thickness of the phosphor film may be varied depending on the shape and size of the light emitting diode, the phosphor films may have a thickness of 5˜40 μm on the side surfaces and the upper surface of the light emitting diode 25a.

According to the present invention, since the phosphor paste 28′ is applied only onto the upper and side surfaces of the light emitting diode 25a, it is not required on an upper surface of the package substrate 21 and an inner reflective surface of the cap structure 22, and thus, more uniform distribution of the phosphor paste can be obtained.

Additionally, as shown in FIG. 2d, after curing the phosphor paste 28′ applied onto the light emitting diode, a transparent molding portion 29 may be formed inside the cap structure 22 by use of the transparent resin. The transparent molding portion 29 is provided in order to protect the light emitting diode 25a mounted on the package substrate 21, and may be formed by use of a typical transparent resin, which does not contain the phfosphor powders. Moreover, in order to electrically connect the light emitting diode 25a (more specifically, the light emitting diode chip 25) to the lead frames 23a and 23b, a wire bonding process is performed after curing the phosphor paste 28′ and before forming the transparent molding portion 29. This serves to prevent the droplets of the phosphor paste 28′ dispended in a small amount from unnecessarily moving along wires 24a and 24b.

Operation and advantageous effects of the present invention will now be described in detail with reference to an inventive example.

### INVENTIVE EXAMPLE

In the inventive example, a flip-chip light emitting diode having light emitting diodes (320×300×80 μm) mounted as a flip chip on a substrate was mounted on a package substrate. Phosphor paste having a viscosity of about 4,000 cps was prepared by mixing a silicon-based curable resin as a transparent polymer resin and TAG-based phosphor powders in a weight ratio of about 7:1. The phosphor paste was supplied to an upper surface of the light emitting diode by a dispensing process. In the dispensing process, a droplet of the phosphor paste has a volume of about 0.1 μl. After curing the phosphor paste for a predetermined time so as to allow the phosphor paste dispensed on the upper surface of the light emitting diode to be applied onto side surfaces of the light emitting diode as well as the upper surface, a phosphor film is provided on the upper surface and side surfaces. As a result, the phosphor film has a thickness of about 20 μm on the upper surface of the light emitting diode while having a thickness of about 15 μm on the side surfaces thereof. Subsequently, terminals of the flip chip light emitting diode (located on the upper surface of the substrate for the flip chip light emitting diode) are connected to lead frames of the package substrate by means of wire bonding, and then a transparent molding portion was formed by use of the same silicon-based curable resin as that constituting the phosphor paste.

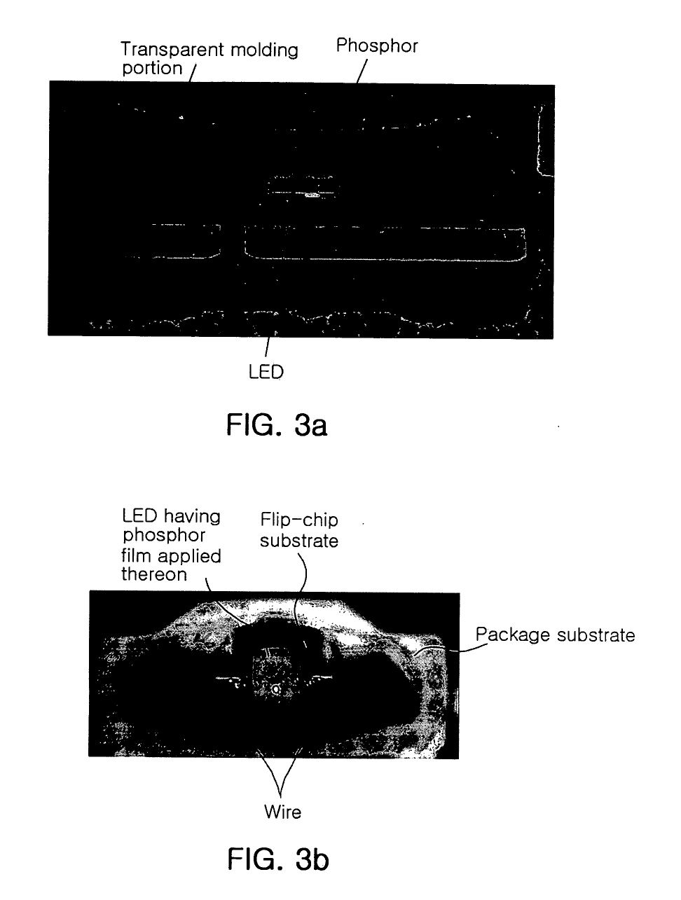

FIG. 3a is a picture of a white light emitting diode package of the inventive example, which was taken using a SEM, and FIG. 3b is a picture of an upper surface of the white light emitting diode package of the inventive example.

Referring to FIG. 3a, it can be seen that the phosphor is applied in a substantially uniform thickness on the upper surface and the side surfaces of the light emitting diode of the light emitting diode chip. As such, the phosphor can be applied in the uniform distribution on the upper surface and the side surfaces of the light emitting diode of the light emitting diode chip by use of high viscosity phosphor paste in a small amount according to the present invention. Additionally, referring to FIG. 3b, it can be seen that the phosphor film is applied only onto the light emitting diode on the flip-chip substrate.

### COMPARATIVE EXAMPLE

In the comparative example, although the same light emitting diode package and dispensing process as those of the inventive example are applied, conventional phosphor paste having a viscosity not in a range of the present invention was used. More specifically, the phosphor paste was prepared by mixing an epoxy-based curable resin as a transparent polymer resin and TAG-based phosphor powders in a weight ratio of about 1:8, and was supplied to an upper surface of the light emitting diode by the dispensing process, thereby manufacturing a light emitting diode package.

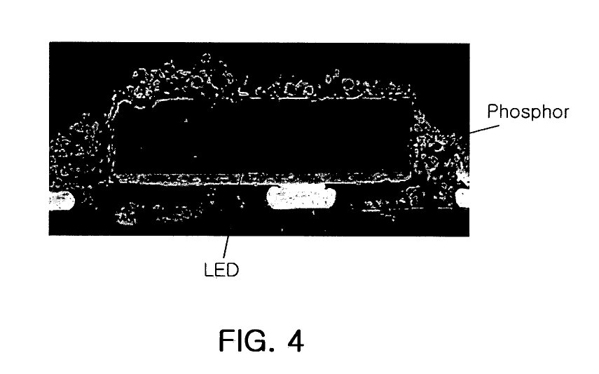

FIG. 4 is a picture of a white light emitting diode package of the comparative example taken using the SEM, and illustrating an applied state of a phosphor film on the white light emitting diode package of the comparative example.

Referring to FIG. 4, unlike the light emitting diode package shown in FIGS. 3a and 3b, the phosphor is non-uniformly distributed on the light emitting diode, and particularly, it can be seen that the phosphor is widely distributed around the side surfaces of the light emitting diode. As such, when the conventional phosphor mixture having a composition outside the range given in the present invention is supplied on the upper surface of the light emitting diode in a small amount, a desired uniform thickness of the phosphor film cannot be obtained.

As apparent from the above description, according to the present invention, the high viscosity phosphor paste is supplied on the upper surface of the light emitting diode in a small amount, and applied only onto the upper and side surfaces of the light emitting diode, thereby solving the problems of non-uniform distribution and dispersion of the phosphor caused by deposition of the phosphor powders. Accordingly, there are provided advantageous effect of excellent light conversion efficiency, and of preventing the brightness of the reflective region on the upper surface of the package substrate from being lowered due to the deposition of the phosphor powders.

It should be understood that the embodiments and the accompanying drawings have been described for illustrative purposes and the present invention is limited only by the following claims. Further, those skilled in the art will appreciate that various modifications, additions and substitutions are allowed without departing from the scope and spirit of the invention as set forth in the accompanying claims.

1. A method of manufacturing a white light emitting diode package, comprising the steps of:
mounting a light emitting diode on a package substrate having at least one lead frame;
preparing phosphor paste having a viscosity of 500˜10,000 cps by mixing phosphor powders and a transparent polymer resin;
dispensing liquid droplets of the phosphor paste on an upper surface of the light emitting diode such that the phosphor paste is applied onto the upper surface and side surfaces of the light emitting diode; and
curing the phosphor paste applied onto the light emitting diode.

2. The method as set forth in claim 1, wherein the phosphor paste has a weight ratio of the paste powders to the transparent polymer resin in the range of 0.5˜10.

3. The method as set forth in claim 1, wherein the liquid droplet of the phosphor paste has a volume of 0.012˜0.5 μl.

4. The method as set forth in claim 1, wherein the transparent polymer resin is a curable polymer resin.

5. The method as set forth in claim 4, wherein the curable polymer resin is one of a silicon-based polymer resin and an epoxy-based polymer resin.

6. The method as set forth in claim 1, further comprising the step of electrically connecting the light emitting diode or the light emitting diode chip to the lead frame by use of wires, after the step of curing the phosphor paste.

7. The method as set forth in claim 1, wherein the light emitting diode is a flip chip light emitting diode.

8. The method as set forth in claim 1, wherein the package substrate further comprises a cap structure enclosing the light emitting diode on an upper surface of the package substrate, and the method further comprises the step of forming a transparent molding portion inside the cap structure by use of the transparent resin after the step of curing the phosphor paste.

9. A white light emitting diode package manufactured by a method as set forth in claim 1.

10. A white light emitting diode package manufactured by a method as set forth in claim 2.

11. A white light emitting diode package manufactured by a method as set forth in claim 3.

12. A white light emitting diode package manufactured by a method as set forth in claim 4.

13. A white light emitting diode package manufactured by a method as set forth in claim 5.

14. A white light emitting diode package manufactured by a method as set forth in claim 6.

15. A white light emitting diode package manufactured by a method as set forth in claim 7.

16. A white light emitting diode package manufactured by a method as set forth in claim 8.
